(19) United States
(12) Patent Application Publication
(10) Pub. No.: US 2002/0008287 A1
(43) Pub. Date: Jan. 24, 2002

(54) Electrostatic discharge protective structure

(76) Inventors: Martin Czech, Freiburg (DE); Peter Graf, Teningen-Nimburg (DE)

Correspondence Address: Samuels, Gauthier & Stevens LLP, 225 Franklin Street, Suite 3300, Boston, MA, 02110, US

(21) Appl. No.: 09/852,064

(22) Filed: May 8, 2001

(30) Foreign Application Priority Data
May 8, 2000 (DE) 100 22 368.0

(51) Int. Cl. H01L 23/62

(52) U.S. Cl. 257/363; 257/355; 257/360

(57) ABSTRACT

An electrostatic discharge (ESD) protective structure is configured to protect an integrated circuit, which is connected between a first voltage bus with a first supply voltage and a second voltage bus with a second supply voltage. The ESD protective structure includes a plurality of laterally designed bipolar transistors, whose load lines are arranged parallel to one another and between the voltage buses, and whose control connections are connected to one of the voltage buses. A resistor track is disposed in the load line of each bipolar transistor and is co-integrated into the ESD protective structure on the collector side and/or the emitter side.

### BACKGROUND OF THE INVENTION

The invention relates to the field of semiconductor devices, and in particular to an electrostatic discharge (ESD) protective structure to protect an integrated semiconductor circuit against electric discharge.

During the operation of integrated circuits undesirably high voltage peaks sometimes occur, which are coupled into the integrated circuit through the supply lines. Without suitable protective measures, parasitic overvoltages of a few volts and the electrostatic discharges caused thereby can damage and even destroy the integrated circuit. Irreversibly. This makes the failure rate of such an integrated circuit unacceptably high.

To reduce their failure rate circuits located on an integrated circuit often contain co-integrated ESD protective structures. These ESD protective structures can be inserted as clamping circuits between the supply lines of the integrated circuit and, in the event of an electrostatic discharge, drain off the parasitic overvoltage to one of the supply lines. As a result, the parasitic overvoltage between the supply lines is reduced to a tolerable value (i.e., to a value that does not damage the integrated circuit).

An important boundary condition in the production of ESD protective structures derives from the requirement that under operational conditions (as these are described for example in the product specification) the ESD protective structures must not impair the function of the integrated semiconductor circuit that is being protected (or impair it only insignificantly). Thus the breakdown or switch-through voltage of the ESD protective element must be beyond nominal the signal voltage range of the circuit being protected.

As a result, the ESD protective element should break down before the critical circuit path, but beyond the signal voltage range. As a rule this requires an exact adjustment of the breakdown and switch-through voltage of the particular ESD protective element.

ESD protective elements often include semiconductor components that are blocking at least part of the time, such as, for example, thyristors, bipolar transistors, field effect transistors, or diodes.

However, ESD diodes have the disadvantage that at high currents the voltage drop across the diode sometimes can become so large that sensitive components of the protected circuit may be irreversibly damaged (e.g., their gate oxides or diffusion regions are damaged). Furthermore, in reverse operation diodes consume a great deal of power.

A disadvantage of ESD thyristors is that once it fires it retains its firing state in an undesirable manner. This firing state may last arbitrarily long and cause a short circuit in the voltage supply and the destruction of the ESD protective structure. As a result, ESD protection for the integrated circuit is no longer assured.

ESD protective structures are often used that have a plurality of parallel, bipolar field oxide transistors as ESD protection. These ESD protective structures are especially well suited to limit overvoltages. With a reverse bias voltage in the characteristic they initially provide a blocking behavior until a first voltage breakthrough is reached, at which point the current-voltage characteristic snaps back to a lower voltage than the breakthrough voltage. This process of snapping back to the lower holding voltage is referred to as snapback behavior.

If such ESD protective structures are used for increasingly miniaturized integrated semiconductor circuits, especially for structural widths less than 0.5 μm the problem arises that due to the small lateral structures, the holding voltage extends into the nominal operating range of the signal voltage of the integrated circuit. If such an ESD protective structure is fired, it remains in this snapped-back state until the supply voltage is turned off. This state results in very high power consumption of the integrated circuit and in the power supply, which can result in permanent thermal damage at the end load.

Thermal instabilities of an ESD bipolar transistor can also short circuit the signal voltage of the entire integrated circuit. Without additional protective measures this may have catastrophic consequences, including destruction of the integrated circuit.

Consequently, there is a need for the holding voltage to lie definitively and reliably outside the signal voltage range, even with variations of manufacturing technology. The holding voltage consequently should be pushed as much as possible toward higher currents and voltages.

Therefore there is a need for an ESD protective structure wherein the holding voltage lies outside the nominal operating signal voltage range of the protected circuit.

### SUMMARY OF THE INVENTION

Briefly, according to an aspect of the present invention, an electrostatic discharge (ESD) protective structure is configured to protect an integrated circuit, which is connected between a first voltage bus with a first supply voltage and a second voltage bus with a second supply voltage. The ESD protective structure includes a plurality of laterally designed bipolar transistors, whose load lines are arranged parallel to one another and between the voltage buses, and whose control connections are connected to one of the voltage buses. A resistor track is disposed in the load line of each bipolar transistor and is co-integrated into the ESD protective structure on the collector side and/or the emitter side.

The emitter electrodes and/or the collector electrodes are disposed on the contacted regions, such that the mean free path of the charge carriers between the respective electrodes and the substrate is lengthened. These additionally inserted distances in the emitter zones and collector zones exceed the conventional distance prescribed by conventional design rules. Through these additional distances, a desired emitter and collector path resistance can be adjusted in a specific and defined manner.

An integrated emitter path resistance is thus inserted in the emitter zone, and an integrated collector path resistance is inserted in the collector zone. Inserting the collector path resistance prevents the thermal instability of the bipolar transistors of the ESD protective structure. Inserting the integrated emitter path resistance causes negative feedback of the current, thus achieving the holding voltage required to provide effective ESD protection. The holding voltage is thus adjustable in a defined manner.

Collector path resistances typically are much higher than emitter path resistances.

Emitter zones and collector zones may be laterally enclosed by the base zones, which assures latch-up protection for the ESD protective structure. This latch-up protection may be improved by embedding the zones of the ESD structure (i.e., the emitter zones, collector zones, and base zones) in an additional well so that they are isolated from the substrate potential.

In one embodiment, the emitter zones and collector zones are designed in strips.

The strip-shaped collector zones and emitter zones are arranged parallel to one another, such that the collector zones and emitter zones alternate. The ESD protective structure may be configured and arranged in an essentially square layout, which assures homogenization of the current of the ESD structure. Further homogenization of the current can be achieved in that the emitter zones and collector zones are through-contacted by the respective electrodes.

In one embodiment each of the strip-shaped emitter electrodes and collector electrodes forms a finger-like structure with the conductor track to which they are connected. These finger-like structures are preferably staggered with one another. As a result, large current densities and large voltage drops occur at opposite sides of the respective conductor tracks, thus reducing scorching at the conductor tracks caused by voltage breakthroughs.

The ESD protective structure is especially suited for bipolar transistors designed as field oxide transistors.

These and other objects, features and advantages of the present invention will become more apparent in light of the following detailed description of preferred embodiments thereof, as illustrated in the accompanying drawings.

### BRIEF DESCRIPTION OF THE DRAWING

FIG. 1 illustrates a circuit arrangement with an inventive ESD protective structure;

FIG. 2 illustrates a circuit diagram of the inventive ESD protective structure illustrated in FIG. 1;

FIG. 3 illustrates a partial section through an embodiment of the ESD protective structure illustrated in FIG. 2;

FIG. 4 illustrates a magnified section of the ESD protective structure shown in FIG. 3;

FIG. 5 is a top view of a layout for contacting the emitter, base, and collector of the ESD protective structure illustrated in FIG. 3; and

FIG. 6 is a top view of an arrangement of the conductor tracks for contacting the emitter electrodes and collector electrodes.

### DETAILED DESCRIPTION OF THE INVENTION

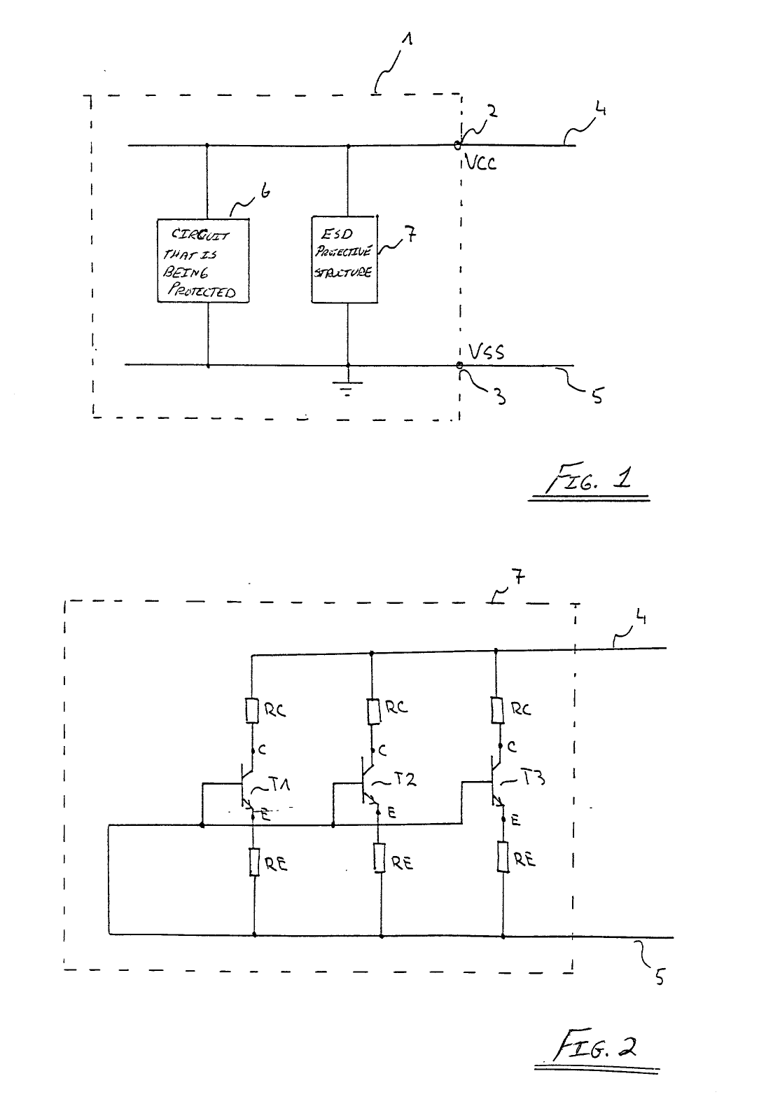

FIG. 1 illustrates an integrated circuit 1. The integrated circuit 1 is connected via supply voltage inputs 2, 3, to a first voltage bus 4 with a first supply voltage VCC and to a second voltage bus 5 with a second supply voltage VSS, respectively. In the present example VSS is reference ground.

The integrated circuit 1 includes a circuit 6 that is being protected (e.g., a logic circuit, a program-controlled unit, a semiconductor memory, a power circuit, etc.). The integrated circuit 1 also includes an ESD protective element 7 to protect the circuit 6. The circuit 6 that is being protected and the ESD protective element 7 are connected between the voltage buses 4, 5.

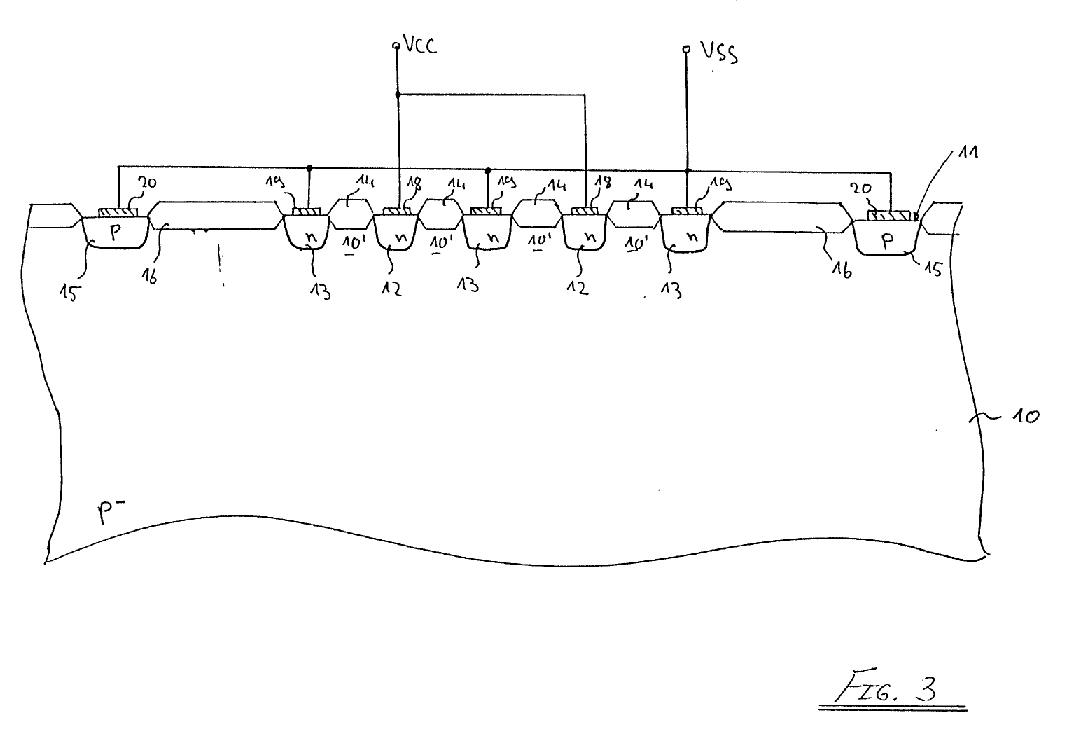

FIG. 2 illustrates a circuit arrangement of the inventive ESD protective structure 7. The ESD protective structure 7 includes a plurality of (e.g., three) bipolar field oxide transistors T1, T2, T3. The bipolar transistors T1-T3 are arranged in parallel across their load lines and are connected between the voltage buses 4, 5. In the present embodiment, the respective emitter connections E are connected to the voltage of the reference ground VSS, and the respective collector connections C are connected to the supply voltage VCC. According to an aspect of the invention, track resistors RC, RE are connected in the collector side and the emitter side, respectively, into the load lines of the bipolar transistors T1-T3. The track resistors RC, RE are co-integrated into the ESD protective structure.

FIG. 3 illustrates a partial section 10 of the ESD protective structure of FIG. 2. In one embodiment a semiconductor body 10 includes a weakly p-doped silicon substrate. The semiconductor body 10 has a wafer front side 11 in which are embedded the first and second n-doped regions 12, 13. The first n-doped regions 12 are the collector zones in the present embodiment; the second n-doped regions 13 are the emitter zones. In this embodiment the collector zones 12 and the emitter zones 13 are arranged alternately on the surface 11, and are spaced apart from one another by a substrate zone 10′ or field oxide 14. P-doped regions 15 that form the base zones are embedded in the semiconductor body 10. The base zones 15 enclose the collector zones 12 and emitter zones 13 and are spaced apart from these, for example, by a field oxide 16.

The collector zones 12, the emitter zones 13, and the base zones 14 have metal electrodes 18, 19, 20, respectively, that are located on the surface 11 of the semiconductor body 10. The collector electrodes 18 are short-circuited with one another and are connected to the first supply voltage VCC. The emitter electrodes 19 and the base electrodes 20 are also short-circuited with one another and are connected to the voltage of the reference ground VSS.

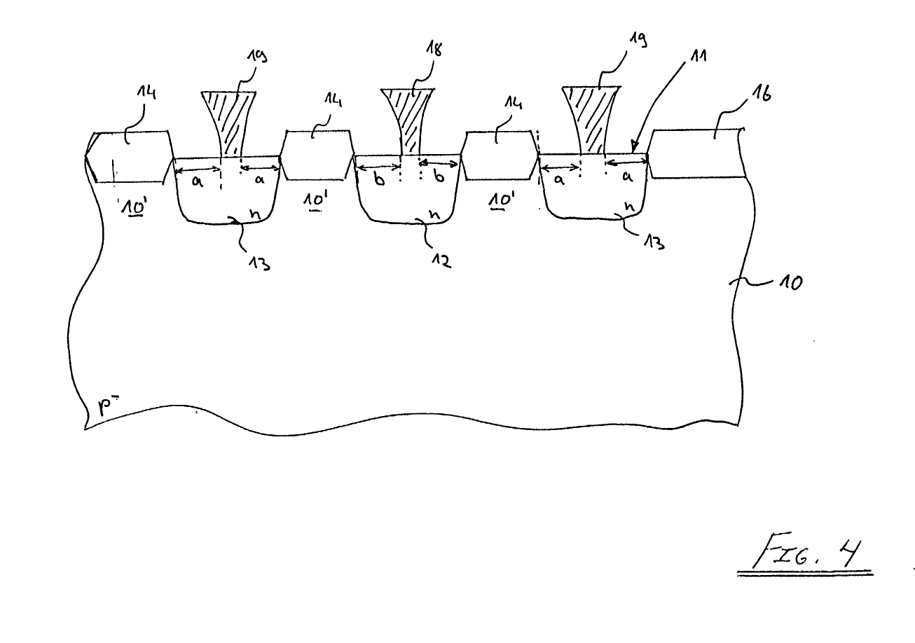

FIG. 4 illustrates a magnified section of the ESD protective structure of FIG. 3. The magnified section illustrates that on the diffusion regions designed as the collector zones 13 and emitter zones 12, the collector electrodes 18 and emitter electrodes 19 have spacings a and b to the edges of the respective diffusion regions. The distance of the spacings a and b are larger than spacing required by the technology through the conventional design rules. In the equivalent circuit diagram corresponding to FIG. 2 the spacings a, b provide collector track resistors RC and emitter track resistors RE.

The track resistors RE, RC for the emitter and collector according to FIG. 2 are formed by the diffusion regions of the respective emitter zones 12 and collector zones 13. That is, the track resistors are co-integrated in the corresponding zones 12, 13. The track resistors RE, RC are provided in the layout illustrated in FIG. 3 by introducing the distance a at the emitter and the distance b at the collector. Of course, with all these contacts lateral minimum distances must be preserved as prescribed by appropriate design rules employed in the fabrication process. However, the inventive structure of FIGS. 3 and 4 involves distances a, b, which exceed the minimum distances required and prescribed by the conventional design rules. Of course, it is conceivable to diffuse the track resistors RE, RC into the semiconductor body 10 by specially diffused resistor regions. However, this would require an additional process step and for economic reasons this is obviously undesirable. The function of the track resistors RE, RC co-integrated into the ESD structure shall now be described in more detail below.

The collector track resistors RC assure a uniform distribution of the ESD current among the bipolar transistors T1-T3. However, if, for whatever reasons, even slightly more current flows through one of the bipolar transistors T1-T3, then to the same extent an increased voltage drop will occur at the associated collector track resistor RC, thus choking the emitter-collector voltage and consequently reducing the load current. In this way the collector currents of the bipolar transistors T1-T3 are regulated within certain limits, resulting in higher stability of the entire ESD protective structure 7. In particular, thermal instabilities of the ESD bipolar transistors are thus essentially avoided.

The amplification of a transistor can be controlled through the emitter resistors RE. In the switched-on state, the collector current flows through the track resistor RE on the emitter side and creates a voltage drop so that the emitter voltage increases with increasing current. If the base voltage remains the same, the base emitter voltage is thus reduced. The decrease of collector current resulting therefrom leads to negative current feedback. A reduction of the effective base emitter voltage is important for the switching behavior of the ESD protective structure, since the holding voltage essentially depends on the emitter resistors RE. The reduction of the effective base-emitter voltage requires a higher base bias voltage, increasing the holding voltage of the ESD protective structure. In this way the dimensioning of the emitter-side track resistors RE assures a safe distance of the holding voltage from the signal voltage region, even with structural sizes such as for example less than 0.5 μm. Without the emitter series resistors RE the entire ESD protective structure may remain in the snapped-back state, resulting in a short circuit with the consequences mentioned in the introduction.

In FIG. 4 the distances a, b are shown essentially the same for ease of illustration. However, in a preferred embodiment the collector distance b is much greater than the emitter distance a. This ensures that the collector resistance RC will be much larger than the emitter resistance RE. The collector distance b thus represents, as it were, a safety distance of the electrodes to the actual collector. Typically, the collector resistors RC should be the same, and the emitter resistors RE should be the same.

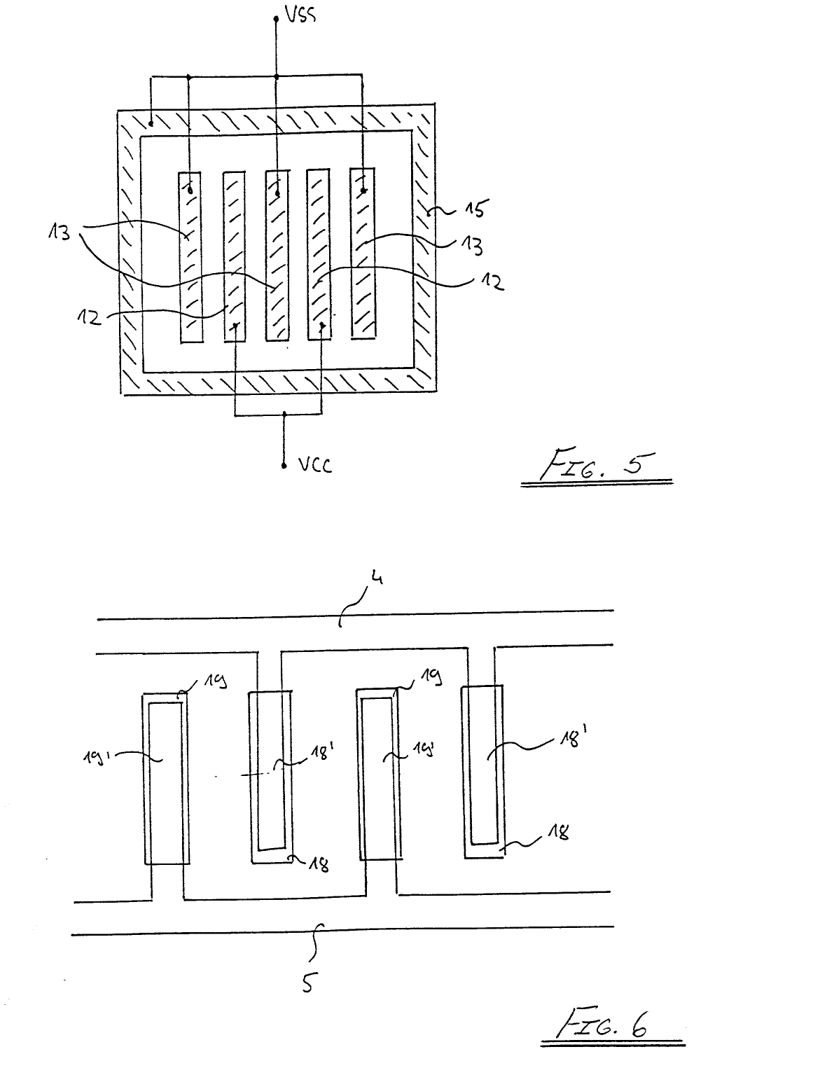

FIG. 5 illustrates a top view of a layout of an ESD protective structure 7 corresponding to the circuit embodiment illustrated in FIG. 2. The entire ESD protective structure 7 preferably has an essentially square layout, which favors uniform current distribution among the various bipolar transistors T1-T3. In this square layout the emitter zones 13 and the collector zones 12 are formed as strips that are arranged parallel to one another. This assures that none of the bipolar transistors T1-T3 in principle “sees” different substrate effects than the respectively adjoining bipolar transistor T1-T3. Furthermore, a square layout prevents the voltage drop of the contact metallization from becoming too large and the creation of a non-uniform current distribution, as would be the case for example for a rectangular non-square layout.

The invention is not limited to square layouts of the ESD protective structures 7. It is contemplated that non-square layouts such as rectangular, round, oval, or hexagonal or similar layouts may also be used. Furthermore, the emitter and collector zones 12, 13 need not be arranged as strips next to one another, but rather may be arranged in circles, squares, serpentines, fanned-out, or the like. The emitter zones 13, collector zones 12, and base zones 15 are through-contacted as much as possible by their respective electrodes 18, 19, 20 to promote homogenization of the current flow.

FIG. 6 illustrates a top view of an arrangement of the conductor tracks for contacting the emitter electrodes and the collector electrodes. This view illustrates two metallizations for the voltage busses 4, 5. Furthermore, FIG. 6 illustrates the respective strip-shaped emitter electrodes 19 and collector electrodes 18, arranged next to one another. These electrodes 18, 19 are connected via finger-shaped metallizations 18′, 19′ to their respectively associated voltage busses 4, 5. In this arrangement the metallization fingers 18′, 19′ are staggered and are connected to the mutually opposite voltage buses 4, 5, respectively.

During operation of the ESD protective structure 7 there are unavoidable voltage drops at its electrodes 18, 19, such that, usually the greatest voltage difference between emitter and collector appears at the front ends of the electrodes 18, 19. Consequently, the current densities are highest there and the electrodes 18, 19 may break down due to scorching. The arrangement of the metallization fingers 18′, 19′ shown in FIG. 5 essentially precludes this problem, since the metallization fingers 18′, 19′ are connected only to one of the opposite voltage buses 4, 5. Voltage drops still occur along the respective metallizations, but with an alternating collector electrode 18 and emitter electrode 19 they occur in opposite directions so that a voltage difference between the collector electrode 18 and the emitter electrode 19 remains the same. In addition, the layout measure of FIG. 5 favors a more homogeneous current distribution on the entire surface of the ESD protective structure 7.

The ESD protective structures may be arranged next to one another arbitrarily often. It should be noted here that the p-doped base zones 15 are preferably arranged outside, and the collector zones 12 and emitter zones 13 are surrounded by them. Because the base zones 15 surround the zones 12, 13, the ESD protective structure 7 is held at a defined voltage thus assuring improved latch-up protection. However, it is contemplated that the base zones 15 do not completely enclose the zones 12, 13, but such a structure offers less latch-up protection.

The ESD protective structure described in the embodiments has only three bipolar transistors T1-T3; in the layout, this ESD protective structure consequently has three emitter fingers and two collector fingers. Of course, the present invention can also be implemented with more or fewer bipolar transistors. An important point here is symmetry, that is the emitter zones 13 and collector zones 12 are arranged as symmetrically to one another as possible. Furthermore, the emitters should lie outside as much as possible to exclude parasitic edge effects.

The base zones 15, collector zones 12, and emitter zones 13 illustrated in FIGS. 3 and 4 may be introduced into the semiconductor body 10 by diffusion or by ion implantation. The selected doping method is essentially guided in accordance with the particular manufacturing processes for the integrated circuit.

With respect to the embodiments illustrated in FIGS. 3 and 4, it is contemplated that conductivity types n and p may be interchanged. Furthermore, for the sake of completeness, it should be pointed out that the lateral and vertical dimensions in FIGS. 3 and 4 naturally have not been shown to scale. For example, for the sake of ease of illustration, the vertical dimensions are shown greatly magnified compared to the lateral dimensions.

The ESD protective structure 7 avoids the problems of thermal instability of the bipolar transistors and too low a holding voltage with consequent destruction or damage to the ESD protective structure. A solution of the problem is achieved almost exclusively by device layout control, and consequently requires no expensive special processes or special masks. Only a very slight extra expense for chip surface is needed here for the wider diffusion regions; however, the self-protective effect of the above-described ESD protective structure can be substantially increased thereby.

The inventive ESD protective structure is especially suited for MOS-/CMOS-integrated circuits, which require protection of the supply voltage lines and also of the inputs and outputs. This includes integrated circuits with analog and digital functions with their own analog supply voltage, especially circuits that operate at a high operating voltage and thus do not have inherent protection.

The inventive ESD protective structure constructed and operated as described assures optimal ESD protection by widening the diffusion regions or the implantation regions, without at the same time having to accept the disadvantages of the prior art ESD protective structure with a large number of bipolar transistors.

Although the present invention has been shown and described with respect to several preferred embodiments thereof, various changes, omissions and additions to the form and detail thereof, may be made therein, without departing from the spirit and scope of the invention.

What is claimed is:

1. An electrostatic discharge protective structure arranged to protect an integrated circuit connected between a first voltage bus having a first supply voltage (VCC) and a second voltage bus having a second supply voltage (VSS), said protective structure comprising:
a plurality of laterally designed bipolar transistors each having a first load line connected to the first voltage bus and a second load line connected to the second voltage
bus to one another, wherein said first load lines are electrically parallel and said second load lines are electrically parallel to one another, each of said transistors includes a control connection connected to one of the voltage buses;
a collector resistor track disposed in said first load line of each of said bipolar transistors, wherein said collector resistor track is co-integrated into the ESD protective structure; and
an emitter resistor track disposed in said second load line of each of said bipolar transistors, wherein said emitter resistor track is co-integrated into the ESD protective structure.

2. The electrostatic discharge protective structure of claim 1, comprising a semiconductor body in which are embedded at least one emitter zone and at least one collector zone of the first conduction type and at least one base zone of the second, opposite conduction type, such that said zones of the first conduction type are arranged alternatingly next to one another and are distanced from one another by a substrate zone of the second conduction type in such a fashion that a load current path can form between respectively adjoining emitter zones and collector zones.

3. The electrostatic discharge protective structure of claim 2, comprising an emitter electrode disposed on each emitter zone in such a way that a distance (a) between said emitter electrode and a pn-junction of said emitter zone to said substrate zone is defined, such that the distance (a) is a measure of the resistance of the emitter-side resistor track (RE), which is co-integrated into the emitter zone.

4. The electrostatic discharge protective structure of claim 3, comprising a collector electrode arranged on each said collector zone in such a fashion that a distance (b) is defined between said collector electrode and said pn-junction of the collector zone to the substrate zone, such that the distance (b) is a measure of the resistance of the collector-side resistor track (RC), which is co-integrated into said collector zone.

5. The electrostatic discharge protective structure of claim 4, wherein the resistance of said collector-side resistor tracks (RC) is greater than the resistance value of the emitter-side resistor tracks (RE).

6. The electrostatic discharge protective structure of claim 4, wherein said base zones laterally enclose said emitter zones at said collector zones.

7. The electrostatic discharge protective structure of claim 6, wherein said semiconductor body has charge carriers of the first conduction type and that at least one well of the second conduction type is embedded in said semiconductor body, and that said emitter zones, collector zones, and base zones are embedded in said well of the second conduction type.

8. The electrostatic discharge protective structure of claim 7, wherein said emitter zones and said collector zones are designed as strips and are disposed alternatingly next to one another and parallel to one another.

9. The electrostatic discharge protective structure of claim 8, wherein said ESD protective structure is configured and arranged in an essentially square layout.

10. The electrostatic discharge protective structure of claim 8, wherein said emitter zones are through-contacted by said emitter electrodes and said collector zones are through-contacted by said collector electrodes.

11. The electrostatic discharge protective structure of claim 8, wherein said emitter electrodes and said collector electrodes are connected via conductor tracks to oppositely situated voltage buses and configured and arranged to form finger-like connections that are staggered with one another.

12. The electrostatic discharge protective structure of claim 11, wherein said bipolar transistors include field oxide transistors.
